(19) United States
(12) Patent Application Publication
(10) Pub. No.: US 2006/0147820 A1
(43) Pub. Date: Jul. 6, 2006

(54) Phase contrast alignment method and apparatus for nano imprint lithography

(75) Inventors: Matthew E. Colburn, Hopewell Junction, NY (US); Yves C. Martin, Ossining, NY (US); Theodore G. van Kessel, Millbrook, NY (US); Hematha K. Wickramasinghe, San Jose, CA (US)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: International Business Machines Corporation, Armonk, NY (US)

(21) Appl. No.: 11/028,799

(22) Filed: Jan. 4, 2005

(51) Int. Cl. G03F 9/00; B29C 59/02; B29C 35/08

(52) U.S. Cl. 430/22; 264/293; 264/496; 425/174.4; 425/385

(57) ABSTRACT

An apparatus (and method) for forming a pattern on a workpiece, includes an optical phase contrast image sensor, and an imprint lithography system coupled to the optical phase contrast image sensor for laterally aligning an imprint template feature relative to the workpiece.

### BACKGROUND OF THE INVENTION

1. Field of the Invention

The present invention generally relates to a phase contrast alignment method and apparatus, and more particularly to a phase contrast alignment method and apparatus for use in nano imprint lithography.

2. Description of the Related Art

Imprint lithography typically employs a transparent mold (e.g., also referred to as a “mask” or “die”) to impress a pattern into a liquid (or viscous) photoresist formed over a substrate or workpiece.

When it is desirable to align the template pattern being printed to the underlying workpiece pattern, it is necessary to image alignment targets in both the template and the workpiece simultaneously. However, a problem arises in that, the indices of the resist (e.g., index 1.6) and the quartz mold (e.g., index 1.45) differ by a small amount, and thus it is difficult (or impossible) to optically image the template pattern due to the lack of optical contrast.

In some respects, the problem can be analogized to viewing an object through a glass slide in an aquarium. That is, in the context of the conventional nano-lithography, one has a piece of glass and one is interested in viewing resist-filled indentations in the glass. Hence, there may be high contrast features below on the underlying level, but relative to the mask target, there is an index 1.45 material (e.g., glass) having indentations filled with an index 1.65 material.

Thus, there is not always a sufficient amount of contrast to allow both the mask and the wafer to be imaged simultaneously due to the small index mismatch. This is a significant problem for measuring alignment which typically benefits from having both mask and wafer patterns imaged simultaneously with clear contrast.

The present invention addresses these problems in the context of imprint lithography where transparent masks are used. Hence, prior to the present invention, there have been no optical phase contrast methods or apparatus for enhancing the optical contrast of these targets to allow greater visibility relative to the underlying marks.

Further, the few conventional systems that exist use bright field optics to image the alignment targets.

### SUMMARY OF THE INVENTION

In view of the foregoing and other exemplary problems, drawbacks, and disadvantages of the conventional methods and structures, an exemplary feature of the present invention is the integration of an optical phase contrast method (and apparatus) with an imprint lithography system for enhancing the optical contrast of targets having a very low index mismatch, to allow greater visibility relative to the underlying marks.

In a first aspect of the present invention, an apparatus (and method) for forming patterns on a workpiece, includes an optical phase contrast image sensor, and an imprint lithography system coupled to the optical phase contrast image sensor for laterally aligning template features relative to the workpiece.

With the unique and unobvious aspects of the present invention, optical phase contrast methods and apparatus are provided for enhancing the optical contrast of these targets to allow greater visibility relative to the underlying marks.

Further, when used at maximum extinction, these phase contrast methods of the present invention are typically more robust and predictable that brightfield techniques.

### BRIEF DESCRIPTION OF THE DRAWINGS

The foregoing and other exemplary purposes, aspects and advantages will be better understood from the following detailed description of an exemplary embodiment of the invention with reference to the drawings, in which:

FIG. 1 illustrates a side view of an exemplary alignment structure 100 according to the present invention during imprint (Note, this structure is intended to be exemplary. Many alignment structures are possible);

FIG. 2 illustrates a top view of the optical alignment structure 100 of FIG. 1 during imprint;

FIGS. 3A-3C illustrate correspondence between pattern features and digitized optical signals using conventional brightfield technique and an exemplary embodiment of the present invention;

FIG. 4 illustrates an alignment sensor 400 according to the present invention;

FIG. 5 illustrates a phase contrast imaging of a simple alignment target using an exemplary embodiment of a system 500 according to the present invention;

FIG. 6 illustrates a phase contrast image of an alignment target using DIC optics; and

FIG. 7 illustrates a flowchart of a method 700 according to the present invention.

### DETAILED DESCRIPTION OF EXEMPLARY EMBODIMENTS OF THE INVENTION

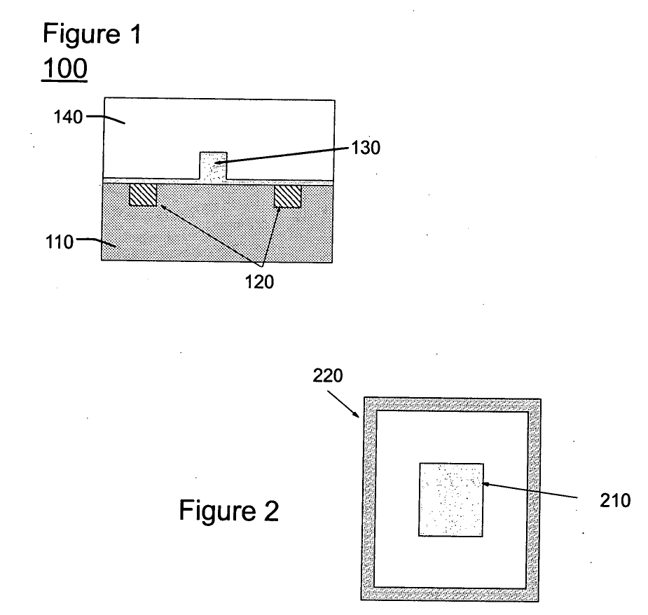

Referring now to the drawings, and more particularly to FIGS. 1-7, there are shown exemplary embodiments of the method and structures according to the present invention.

Generally, the present inventors have recognized that the above problem of imaging when dealing with, for example, an index 1.45 material (e.g., glass) having indentations filled with an index 1.65 material (e.g., photoresist), can be remedied by using a phase contrast optical system in which even though the index mismatch is very low, the contrast becomes very apparent. That is, the phase contrast optical system (e.g., such as a phase contrast microscope) enhances the optical contrast of these targets to allow greater visibility relative to the underlying marks.

Thus, the present invention combines phase contrast methods known in microscopy with an apparatus to perform imprint lithography.

### Exemplary Embodiment

To illustrate further the problem solved by the method and apparatus of the present invention, FIGS. 1 and 2 show a simple two-level alignment structure 100 as it appears, respectively, from the side and from the top.

FIG. 1 shows a side view of the alignment structure 100 during imprint, in which a substrate 110 (e.g., a silicon substrate) has a previously patterned structure 120 formed therein. A resist 130 having a predetermined optical index (e.g., an index of 1.6) is formed on the top surface of the substrate 110. Over the resist 130 is formed a material (e.g., a transparent quartz) mask or die having a predetermined optical index (e.g., an index of 1.45).

In FIG. 2, a pattern 210 being printed (e.g., the box shown in the center of FIG. 2) corresponds to a pattern in the mold (e.g., mask 140) to be centered within a frame structure corresponding to an underlying pattern 220 on the work piece (wafer 110), in order to align the two patterns for imprinting. It is noted that the previously patterned structure 120 corresponds (e.g., the same as) the underlying pattern 220.

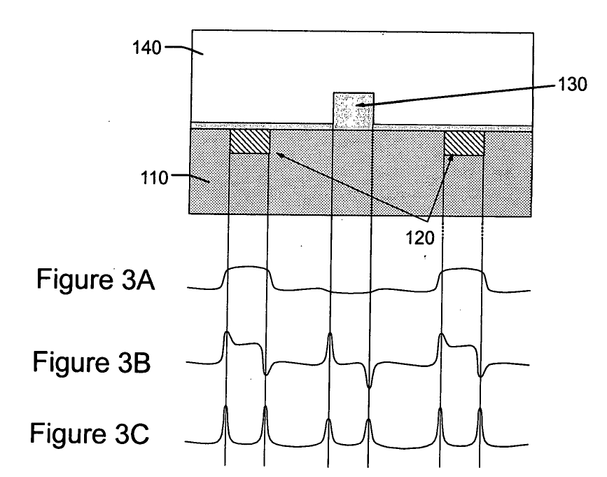

FIGS. 3A-3C illustrate the types of signals that would be generated for the target depicted in FIGS. 1 and 2 using conventional brightfield optics (FIG. 3A) and for phase optics according to the present invention (e.g., FIGS. 3B-3C).

Optical phase contrast methods, as their name implies, enhance the contrast based on optical phase differences between light in different portions of the image. One method, differential phase contrast (DIC) is illustrated herein. This method interferes light from two adjacent local points in the object to form each point in the image with an adjustable phase offset. The effect is similar to differentiation with respect to optical phase. FIGS. 3B and 3C illustrate this effect with a small phase offset (3B) and zero phase offset (3C). Optically, this is accomplished using a Wollaston or Nomarski prism placed behind the objective lens to focus light with different polarization to physically separate points on the subject. The reflected light is subsequently interfered using the same prism to provide the phase contrast observed in the image.

Generally, in order to see a feature which is relatively transparent formed in another relatively transparent material, the invention attempts to use different optical paths through a feature, thereby to view the feature which may be formed on a material having a very similar index to that of an underlying second material on which the first material is formed. Light following one path is retarded to a different degree than light traveling a different path due to the optical index difference.

Thus, the invention makes the feature visible by showing the contrast between the two materials and specifically by making the optical path lengths through one of the features (e.g., groove) different from one another. Hence, one path may be through glass, whereas another optical path may be through a second material such as photoresist, etc.

Thus, the invention uses the fact that different optical paths through a feature will show a contrast of the feature even through the feature is relatively transparent and is formed on another relatively transparent material. For example, it is noted that the groove 130 will show up darker or lighter depending upon the technique used to image it. Hence, through the groove 130, the optical path will be different from that which goes through the resist.

Thus, turning to FIGS. 3A-3C, there are two images which are of interest in viewing at the same time. One image is from the pattern in the wafer below (e.g., structure 120) (for all purposes, this image is assumed to be extremely visible whatever is done), whereas the second image is from the pattern in the mask (e.g., structure 130 which is based in the resist). The second image (e.g., in the mask) is the feature whose contrast the invention is trying to bring up (e.g., feature of interest).

Hence, the invention is attempting to measure a change of phase in an index 1.6 material when the light goes through the resist, to when the light goes through a mask material having an index of 1.45. The light is assumed to go from top to bottom (e.g., in FIG. 1), reflects on the wafer and then goes bottom to top. As evident, some rays go through a longer path of resist, and some rays go through a longer path of glass.

Thus, the phase of these two different rays is slightly different since they have been retarded differently by either passing through the resist (e.g., making them more retarded) or they have been less retarded since the rays have passed only through the glass. As known, the retardation is proportional to the index. Hence, the greater the index, the more the retardation.

Thus, there are two phase paths, and these are made to interfere with a reference signal. The reference signal can be either derived from a reflection very close from where the initial two beams are (e.g., Nomarski or Differential Interference Contrast (DIC)), or another more complex method such as with an interferometric system. How the relative phase is adjusted between the signal beam (e.g., the signal of interest) with a reference beam (e.g., which is next to it etc.) can be performed by the invention. That is, the invention can control such adjustments.

FIG. 3A shows a video signal that conventional brightfield optics would produce.

That is, the waveform represents the actual contrast which would be shown (e.g., what is low amplitude would show up black, what is high amplitude would show up white, etc.). It is noted that the signal corresponding to the central target (e.g., resist 130) is very weak, thereby showing very little contrast from the resist field groove in the quartz mask. The signals associated with the previously patterned structures 120 are somewhat stronger.

Then, as shown in FIG. 3B, the phase signal is added to the signal of FIG. 3A. As evident, there is high contrast, but it is very non-symmetric.

That is, FIG. 3B shows a type of signal produced by a Differential Interference Contrast (DIC) configuration (or Nomarski). It is noted that a variety of phase contrast methods can be applied to this problem including Zernike Phase Contrast, Hoffman Modulation Contrast (HMC), and the like. The present invention uses differential interference contrast (DIC) because of its relative simplicity.

With DIC, the phase signal is the difference of phase between two very closely spaced beams, rather than an interference contrast between a light beam which is reflected (e.g., comes back) and an independent reference beam. Thus, in the invention, the interference contrast of the invention is made very locally. Thus, as shown in FIG. 3B, the contrast occurs predominantly in the edges of the groove in the transparent quartz 140.

FIG. 3C illustrates a composite phase and reflectivity signal at maximum extinction (e.g., zero phase offset) using DIC (or Nomarski) optics. In FIG. 3C, the waveform shows high contrast, and the contrast is symmetric, and thus is preferable to those of FIGS. 3A-3B. Again, the phase contrast, for the present purposes, means that it brings out the edges of the structure. Hence, the signals at the edges are very defined (e.g., very large), and clearly show the contrast, thereby being easily detectable. This is in contrast to FIG. 3A in which detection would be very difficult.

Thus, the invention has sufficient control over the absolute phase difference between a reference and a signal which are very close together so that the invention can make the shape of the measured signal change from the wavforms in FIG. 3A to that of FIG. 3B to that of FIG. 3C.

It is noted that moving from FIGS. 3A to 3B to 3C (e.g., from positions A to B to C) occurs by changing the Nomarski phase adjustment (e.g., which allows a reference phase to be changed).

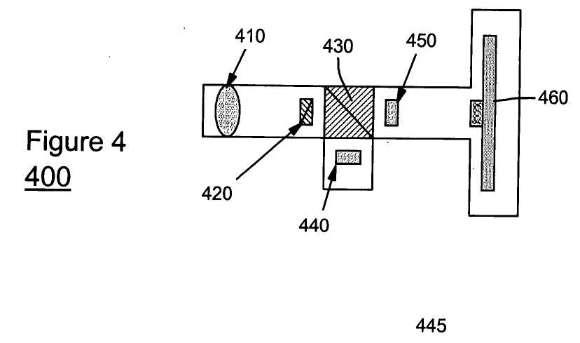

Turning now to FIG. 4, an apparatus 400 (e.g., alignment sensor) according to the present invention is shown. Specifically, the details of the alignment camera is shown in FIG. 4 including the phase contrast optical components.

In FIG. 4, the apparatus includes an objective lens 410, a Wallaston or Nomarski prism 420, a beam splitter 430 adjacent the prism 420, a polarizer 440, an analyzer 450, and a charge coupled device (CCD) image and video electronics 460. There is a light source 445 below the polarizer 440. The light source 445 may be a light emitting diode (LED) or a filtered tungsten halogen source. The LED includes a collimating lens, but optional collimation lenses are understood to be part of the source 445.

In operation, a light beam is emitted by the light source 445 to the polarizer 440. The light goes up through the polarizer 440, and is polarized thereby. For purposes of the exemplary embodiment, the direction of polarization is either in the plane of FIG. 4 or at 90 degrees thereto.

The light reflects at 90 degrees by the beam splitter 430 and goes through the Wallaston or Nomarski prism 420, such that component polarizations of the source light beam are imaged through the objective to two spatially separate points at the mask—sample interface. Thus, the prism 420 makes two spatially distinct beams, each having a path which is slightly different from one another.

The two beams are then focussed by the objective lens 410 very close to each other. In the exemplary application (e.g., the structure shown in FIG. 1), one beam might be in (or close to) the central portion of the resist field groove 130 in the quartz 140, and one beam could be outside of the groove 130. As a result, both beams would have a phase and amplitude which is different from one another.

Then, both beams are passed back through the objective lens 410 to the prism 420 which recombines the beams into one beam. The one beam is sent through the beam splitter 430 and into the analyzer 450. Again, instead of being separated physically, the two beams are recombined by the prism 420 so as to be coincident and interfere with each other.

When the beams are overlapping, the beams interfere, and if the path lengths difference makes a phase difference (e.g., a difference in total intensity is a function of path length difference), then the phase difference between the two interfering beams will be shown as either bright or dark depending upon the phase contrast. Thus, the phase difference will clearly provide the optical contrast.

An exemplary embodiment of the present invention has been developed which utilizes a 0.15 (numerical aperture) NA imaging system with a Wallaston optimized to this NA and narrow band filtered illumination between 550 nm and 650 nm.

The present invention combines the alignment camera with an imprint lithography system as shown.

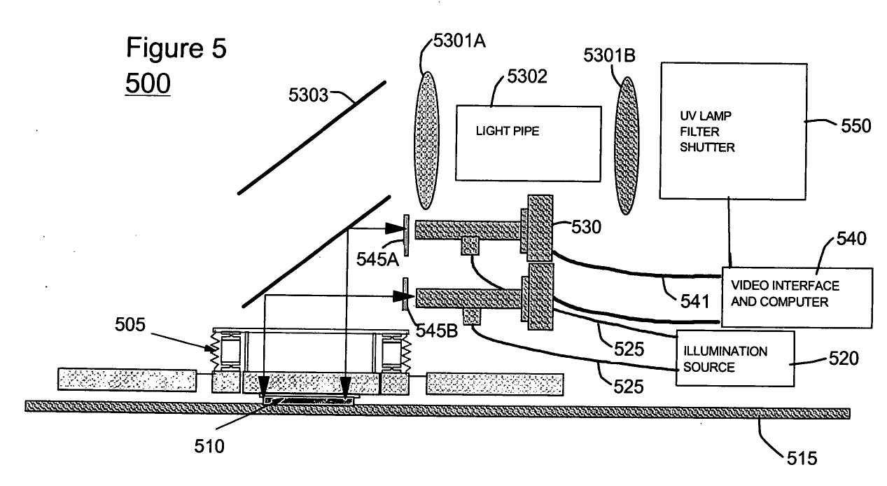

Turning to FIG. 5, the alignment sensor 400 is shown integrated into an optical system 500.

In use, a transparent quartz template 505 holding a mask includes a 6-dimension (e.g., X, Y, Z, θ, φ, ω) flexure capability for maintaining the mask parallel to a surface of a workpiece 515 and performing fine lateral motions of the template.

The mask/template 505 is exemplarily lowered onto the workpiece having a resist 510 coated thereon, and mechanically pressed to cause the resist (e.g., liquid resist) to flow into the template 505 features and across the mask in a uniform manner. Instead of lowering the mask/template to the workpiece, the workpiece could be raised to the mask/template.

Alignment targets are viewed using a DIC alignment camera 530. Light passes from a fiber source 520 via illumination fibers 525, through an alignment sensor 530 (e.g., the same as the structure 400 shown in FIG. 4) as shown, and to the workpiece 515 through the quartz template 515. It is noted that in this embodiment band pass filters are used with an optical fiber illumination system as compared with FIG. 4, where a light emitting diode is used. The alignment sensors 530 are shown with optical band pass filters. The exposure system (e.g., not part of the present invention) is shown and includes objective lens 5301A, 5301B with a light pipe 5302 interposed therebetween, and a beam splitter 5303 with UV lamp, shutter and filter 550.

The polarizer (shown in FIG. 4; not shown in FIG. 5) is oriented at 45 degrees relative to the Wallaston prism (shown in FIG. 4; not shown in FIG. 5) such that a given ray of light propagating through the sensor will image to two spatially separate spots at the template/workpiece interface each with 90 degree polarization relative to the other. The light reflecting from these spots is imaged on the CCD sensor (e.g., sensor 460 shown in FIG. 4).

Along the return path, each orthogonal polarization component is recombined by the Wallaston prism and analyzed. The result is that light reflected from adjacent spatially separated points with an optical phase difference will be imaged with greater or lesser brightness on the CCD. In this manner, contrast is achieved, as shown in FIG. 3C.

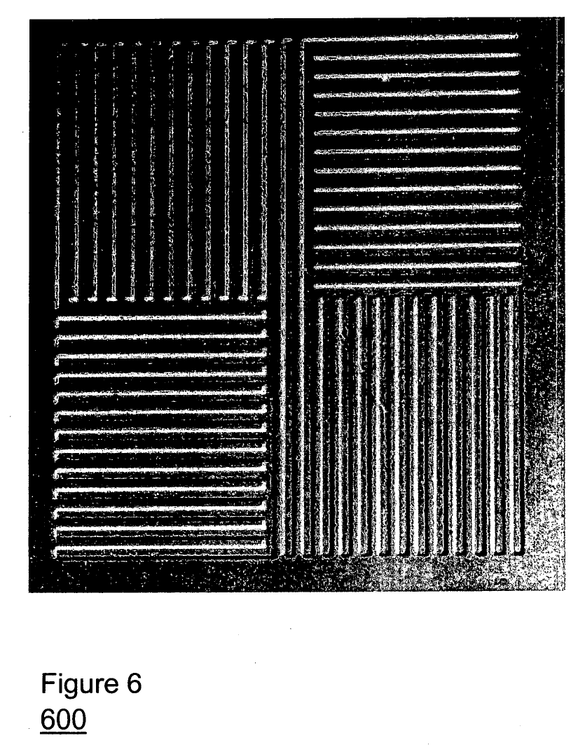

The operation of the inventive system is similar to a Michaelson interferometer where the reference leg of the system is bent to the sample surface. Mathematically, the CCD output signal is proportional to the derivative of phase with respect to diagonal distance on the imaged surface. This effect is shown for a simple alignment target in FIG. 6.

That is, FIG. 6 illustrates a phase contrast image of an alignment target using DIC optics.

Once positioned in the photoresist 510, the lateral position of the template 505 is measured relative to the workpiece 515 by analyzing the video image of the alignment target of the template relative to the image of the alignment target of the workpiece 515. This analysis can be done visually by viewing the target image on a video monitor (not shown), or automatically using a computer 540 configured with a video frame grabber. The computer 540 is coupled to the alignment sensor 530 via video cables 541. In either case, observed errors in the lateral position of the template 505 are corrected using the piezo flexure alignment elements of the imprint system shown in FIG. 4.

Once the template 505 is aligned, it is cured by exposing it to ultraviolet (UV) light from a UV lamp 550 including a filter and shutter. Also shown in FIG. 5 are UV (ultraviolet) filters 545A, 545B for filtering ultraviolet rays for each of the light paths. The template is then removed leaving the properly aligned template pattern in the now cured photoresist.

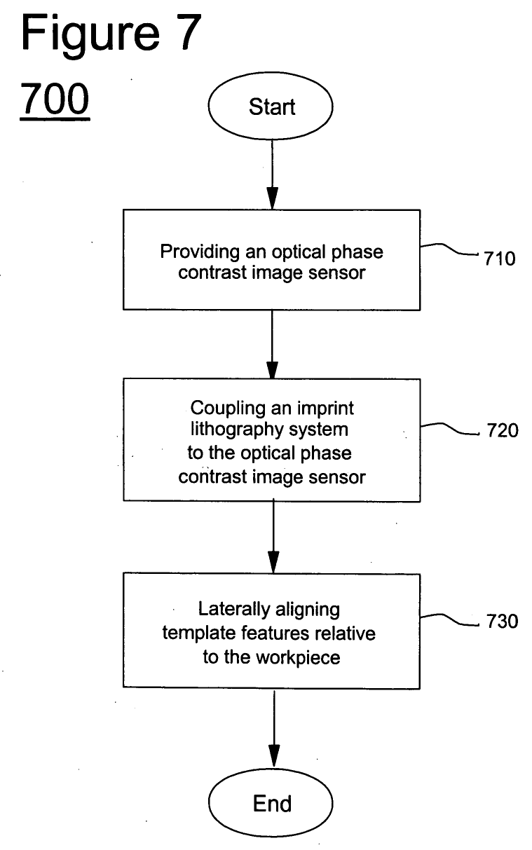

FIG. 7 illustrates a flowchart of a method 700 according to the present invention of forming patterns of a workpiece.

In step 710, the method includes providing an optical phase contrast image sensor.

In step 720, an imprint lithography system is coupled to (e.g., provided for use with) the optical phase contrast image sensor.

In step 730, the template features are aligned relative to the workpiece.

Thus, as described above, with the unique and unobvious aspects of the present invention, optical phase contrast methods and apparatus are provided for enhancing the optical contrast of targets to allow greater visibility relative to underlying marks.

While the invention has been described in terms of several exemplary embodiments, those skilled in the art will recognize that the invention can be practiced with modification within the spirit and scope of the appended claims.

Further, it is noted that, Applicant's intent is to encompass equivalents of all claim elements, even if amended later during prosecution.

It is noted that, there is very little limit on the degree of index similarity. As the mismatch becomes less, the contrast substantially goes down. Practically speaking though, even a few percent is very acceptable. That is, the invention will still be operable even if the index of the first material is substantially the same such as that of the second material.

As mentioned above, the use of band pass filtered light is advantageous to enhancing the contrast, simplifying the resultant image and making optimal use of the imaging optics. This is usually accomplished by filtering the source or using a source such as a light emitting diode which is naturally limited to a narrow range of wavelengths.

What is claimed is:

1. An apparatus for imaging a pattern on a workpiece, comprising:
an optical phase contrast image sensor; and
an imprint lithography system, coupled to said optical phase contrast image sensor, for laterally aligning an imprint template feature relative to the workpiece.

2. The apparatus of claim 1, wherein said optical phase contrast image sensor is based on differential interference contrast (DIC).

3. The apparatus of claim 1, wherein said optical phase contrast image sensor is based on Zernike phase contrast optics.

4. The apparatus of claim 1, wherein said optical phase contrast image sensor is based on Hoffman modulation contrast optics.

5. The apparatus of claim 1, wherein said workpiece is formed of a material having a first index of refraction, filled with a second material having a second index of refraction different than said first index.

6. The apparatus of claim 1, wherein said optical phase contrast system comprises an alignment sensor.

7. The apparatus of claim 1, wherein, to view a feature, which is relatively transparent formed in another relatively transparent material, said phase contrast optical system provides different optical paths through the feature to view the feature by showing a contrast between the two materials.

8. The apparatus of claim 1, wherein the phase contrast optical system makes optical path lengths through a feature different from one another such that a phase of two different rays through the feature is different.

9. The apparatus of claim 1, wherein two phase paths are provided through a feature, which are made to interfere with a reference signal.

10. The apparatus of claim 1, wherein the alignment sensor comprises:
a polarizer for receiving a light beam;
a prism for receiving a polarized light beam from said polarizer, and for forming and recombining first and second light beam portions from said polarized light beam; and
an analyzer for overlapping said first and second light beam portions, to form an overlapping optically interfered beam.

11. The apparatus of claim 10, wherein said alignment sensor further comprises:
a beam splitter interposed between said polarizer and said prism.

12. The apparatus of claim 10, further comprising:
an objective lens for receiving said first and second light beam portions from said prism.

13. The apparatus of claim 10, wherein said prism comprises one of a Wollaston prism and a Nomarski prism.

14. The apparatus of claim 10, further comprising:
a charge coupled device (CCD) for receiving a signal from said analyzer.

15. The apparatus of claim 1, wherein said phase contrast optical system includes:
a polarizer for outputting a polarized light beam; and
a prism for forming first and second spatially distinct light beams from said polarized light beam, each having a path length which is slightly different from one another

16. The apparatus of claim 15, wherein said phase contrast optical system further includes:
an objective lens for focussing said first and second light beams adjacent each other, such that said first and second light beams have a phase which is different from one another.

17. The apparatus of claim 15, wherein said first and second beams are passed back through the objective lens to the prism which recombines the first and second beams into a third beam.

18. The apparatus of claim 15, further comprising:
an analyzer for receiving the recombined beam from said objective lens.

19. A method of forming a pattern on a workpiece, comprising:
providing an optical phase contrast image sensor; and
with an imprint lithography system coupled to the optical phase contrast image sensor, laterally aligning template features relative to the workpiece.

20. A method of imprinting a pattern onto a workpiece, comprising:
lowering a transparent template having a mask therein and having a flexure mount for maintaining the mask parallel to a surface of a workpiece, said workpiece having a resist coated thereon;
mechanically pressing to cause the resist to flow into the template features and across the mask; and
aligning targets on said workpiece.

21. The method of claim 20, wherein said aligning comprises:
passing light through an alignment sensor to the workpiece through the template,
wherein a polarizer of said alignment sensor is oriented relative to a prism such that a ray of light propagating through the sensor images to two spatially separate spots at an interface between the template and the workpiece, each with 90 degree polarization relative to the other; and
imaging light reflected from these spots onto a sensor.

22. The method of claim 21, further comprising:
on a return path, recombining, by the prism, each orthogonal polarization component; and
analyzing the recombined beam.

23. The method of claim 22, wherein a lateral position of the template is measured relative to the workpiece by analyzing an image of an alignment target of the template relative to the image of an alignment target of the workpiece.

24. The method of claim 23, wherein the flexure mount comprises a piezo-driven flexure mount, further comprising:
correcting errors in the lateral position of the template by using the piezo-driven flexure mount.

25. The method of claim 24, further comprising:
curing the photoresist by exposure to ultraviolet (UV) light; and
removing the template, thereby leaving the aligned template pattern in the cured photoresist.
